(19) United States
(12) Patent Application Publication
(10) Pub. No.: US 2013/0279121 A1
(43) Pub. Date: Oct. 24, 2013

(54) ELECTRONIC DEVICE ASSEMBLY STRUCTURE

(71) Applicant: GEMTEK TECHNOLOGY CO., LTD., Hsinchu County (TW)

(72) Inventors: LUNG-HSING LIN, HSINCHU COUNTY (TW); CHI-CHUAN CHU, HSINCHU COUNTY (TW); Chih-Hsu Yen, HSINCHU COUNTY (TW)

(73) Assignee: GEMTEK TECHNOLOGY CO., LTD., HSINCHU COUNTY (TW)

(21) Appl. No.: 13/679,436

(22) Filed: Nov. 16, 2012

(30) Foreign Application Priority Data
Apr. 20, 2012 (TW) 101114118

(51) Int. Cl. H05K 7/06; H05K 7/00

(52) U.S. Cl. CPC H05K 7/06; H05K 7/005
USPC 361/737; 361/679.01

(57) ABSTRACT

An electronic device assembly structure comprises two electronic devices and a fastening unit. Each electronic device includes a body and an electric connection module. The body has at least one opening formed thereon. The electric connection module is located in the body. The fastening unit fastens the two electronic devices together in an integrated manner. The electric connection modules of the two electronic devices form electric connection through the opening.

### FIELD OF THE INVENTION

The present invention relates to an electronic device assembly and particularly to an electronic device assembly structure equipped with modular electronic devices and electric connection modules.

### BACKGROUND OF THE INVENTION

People living in the modern time are flooded with prolific electronic products, and among them computers are the most important ones. These days a growing number of electronic devices are linked to the computers to transmit power or data.

Conventional electronic devices are formed in various shapes. When in use, it is not easy to align them neatly and connect them orderly. A lot of space also is wasted unnecessarily. Moreover, different profiles of electronic devices have to be made with different molds. Fabrication costs are higher and repairs and maintenance also are difficult.

Furthermore, different electronic devices must be connected individually to a computer via multiple connection lines. This is unsightly and occupies a lot of insertion slots. All these show that there are still rooms for improvement.

### SUMMARY OF THE INVENTION

In view of the aforesaid problems, the present invention provides an electronic device assembly structure which includes two electronic devices and a fastening unit. Each electronic device includes a body and an electric connection module. The body has at least one opening. The electric connection module is located in the body. The fastening unit fastens the two electronic devices together in an integrated manner. The electric connection modules of the two electronic devices form electric connection through the opening.

The electronic device assembly structure of the invention thus formed allows multiple sets of electronic devices to be fastened without extra accessories, hence usability improves. Assembly time and manpower of the electronic devices also can be saved. Moreover, during assembly, all the elements are visible clearly, thus assembly error and damage of the elements can be reduced.

In addition, the electronic devices and connection module of the invention adopt modular design, hence can reduce fabrication difficulty and achieve product consistency. Redundant mold making and circuit design are unnecessary. Hence production cost can be greatly reduced.

Moreover, through the electronic device assembly structure of the invention, the number of electronic devices can be increased or decreased (to add or reduce the function of the electronic device assembly structure) according to user's requirements, hence the invention can be widely utilized.

The foregoing, as well as additional objects, features and advantages of the invention will be more readily apparent from the following detailed description, which proceeds with reference to the accompanying drawings. The descriptions and drawings serve merely for illustrative purpose and are not the limitations of the invention.

### BRIEF DESCRIPTION OF THE DRAWINGS

FIG. 1A is an exploded view of an electronic device assembly structure of the invention.

FIG. 1B is a perspective view of an embodiment of an electronic device of the invention.

FIG. 1C is a perspective view of another embodiment of an electronic device of the invention.

FIG. 2A is a perspective view of the electronic device assembly structure of the invention in an assembled condition (with the latch arm turned to a first position).

FIG. 2B is a perspective view of the electronic device assembly structure of the invention in another assembled condition (with the latch arm turned to a second position).

FIG. 3 is a schematic view of the electric connection module of the invention.

FIG. 4 is an exploded view of a second embodiment of an electronic device assembly structure of the invention.

FIG. 5A is a perspective view of another embodiment of an electronic device assembly structure of the invention in an assembled condition.

FIG. 5B is a fragmentary enlarged view according to portion A in FIG. 5A.

### DETAILED DESCRIPTION OF THE PREFERRED EMBODIMENTS

### First Embodiment

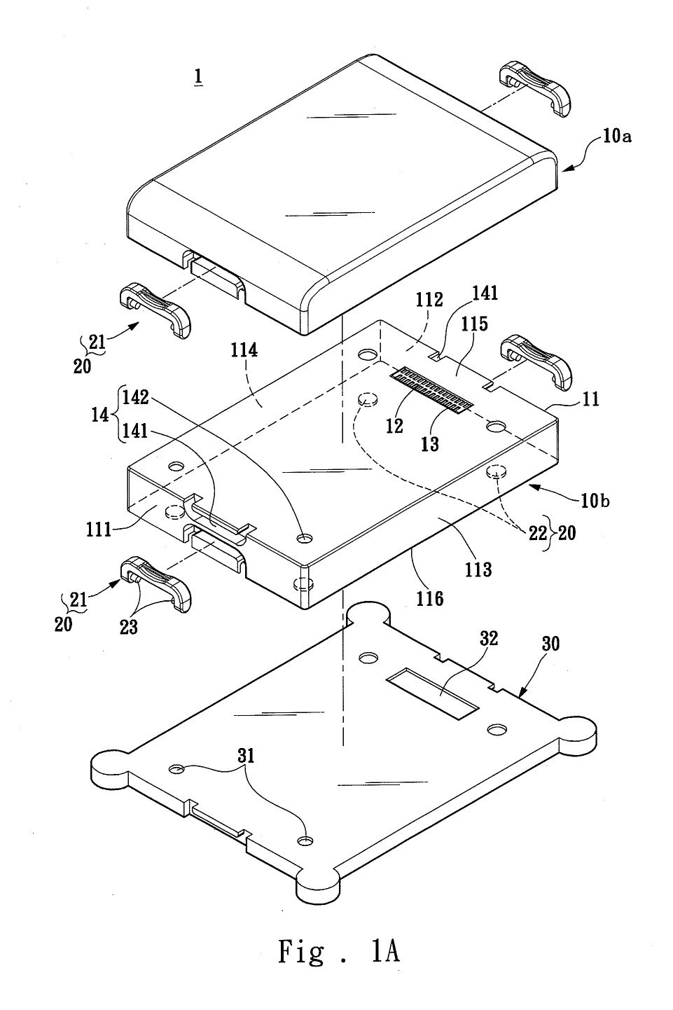

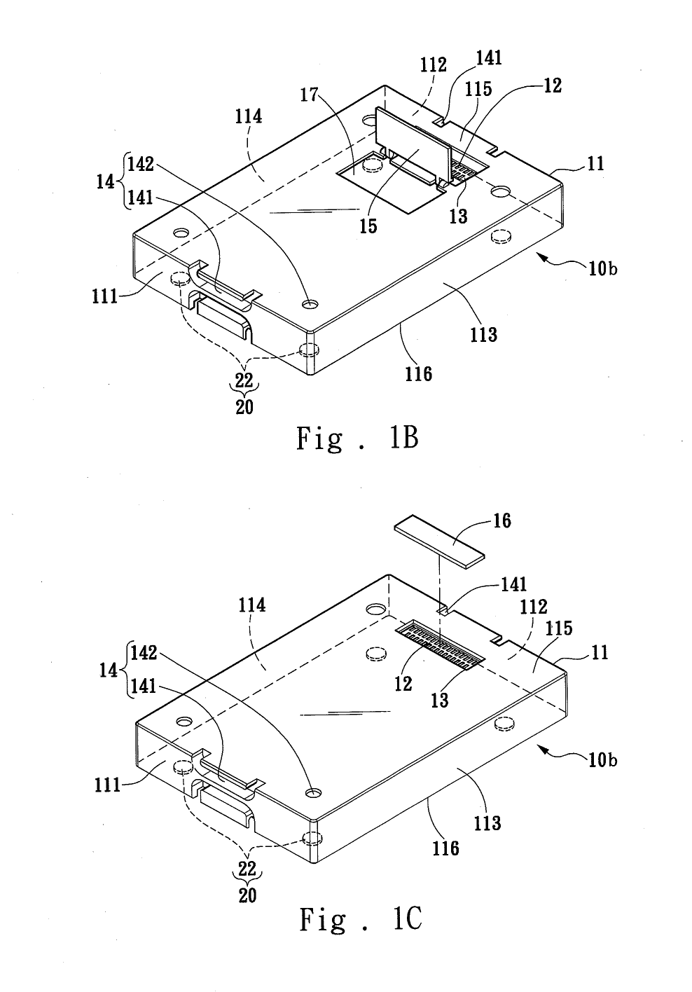

Please refer to FIG. 1A, the present invention aims to provide an electronic device assembly structure 1 that comprises at least two electronic devices 10a and 10b, and a fastening unit 20. While two electronic devices 10a and 10b are employed as an example for discussion herein, they are not the limitations of the invention.

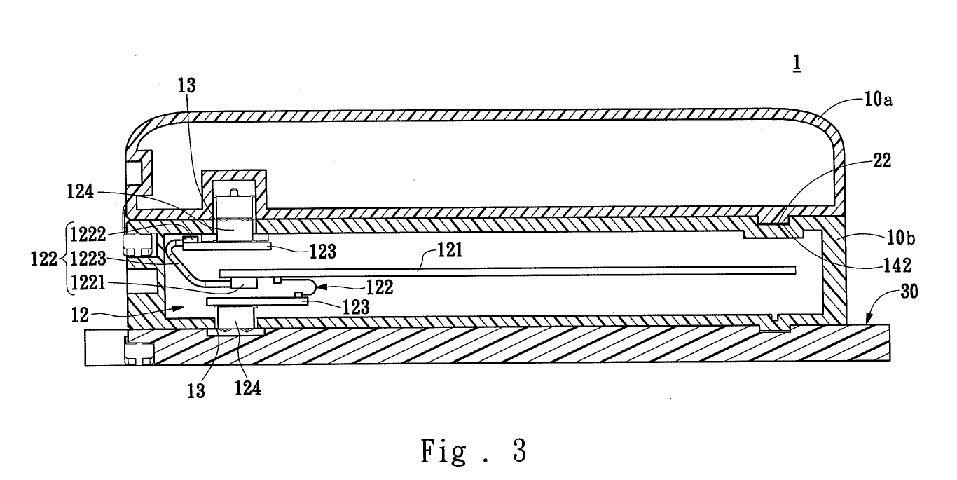

Also referring to FIG. 3, in this embodiment one electronic device 10a is stacked over another electronic device 10b. The electronic device 10b includes a body 11 and an electric connection module 12. The body 11 has at least one opening 13. The electric connection module 12 is located in the body 11. The fastening unit 20 fastens the two electronic devices 10a and 10b together in an integrated manner. The electric connection module 12 of the electronic device 10b is electrically connected to the electric connection module 12 of the electronic device 10a through the opening 13.

In this embodiment, the electronic device 10b further includes a coupling portion 14 connecting to the fastening unit 20. The coupling portion 14 has a plurality of positioning slots 141 and a plurality of positioning holes 142. The positioning slots 141 are located on outer side walls of the body 11, and the positioning holes 142 are formed on another outer side wall on the same plane where the opening 13 is formed.

More specifically, the body 11 has the side walls divided into a front wall 111, a rear wall 112, a left wall 113, a right wall 114, an upper wall 115 and a lower wall 116. The positioning slots 141 are formed respectively in a U shape and located on the front wall 111 and rear wall 112. The opening 13 and positioning holes 142 are located on the upper wall 115. More specifically, the positioning holes 142 are located on the upper wall 115 proximate the circumference thereof. The opening 13 is located between any two positioning holes 142. It is to be noted that the shape and structure of the body 11 are not restricted, and can be rectangular or cylindrical.

In addition, the electronic device assembly structure 1 of the invention further has a base 30 at the bottom of the another electronic device 10b. In this embodiment the base 30 is formed at an area about 1.5 times of the area of the electronic device 10a and 10b. Hence when the electronic devices 10a and 10b are stacked over each other higher in a greater number they are positioned steadier and do not topple over easily. The base 30 has a plurality of positioning apertures 31 and a holding groove 32. Hence when multiple electronic devices 10a and 10b are stacked over the base 30, the base 30 can provide steady support for the electronic devices 10a and 10b. As a result, assembly of the electronic devices 10a and 10b does not require extra accessories, and the problem of loss of the accessories can be eliminated. Moreover, during assembly each element can be seen clearly to reduce assembly error and damage of the element.

Please referring to FIG. 1B, the another electronic device 10b can further include at least one lid 15 corresponding to the opening 13 that is hinged on the body 11 to guard the electric connection module 12 against dust, moisture or static charges and prevent the electric connection module 12 from being damaged, twisted or deformed caused by impact.

The lid 15 can be made from plastics and hinged on the body 11 by latching. The upper wall 115 of the body 11 further has a holding recess 17 to hold the flipped lid 15. Hence by flipping the lid 15 the electric connecting module 12 is exposed. Or referring to FIG. 1C, in an embodiment variation the another electronic device 10b can include at least one protective cap 16 corresponding to the opening 13 that is securely latched on the opening 13 to provide the effects mentioned above.

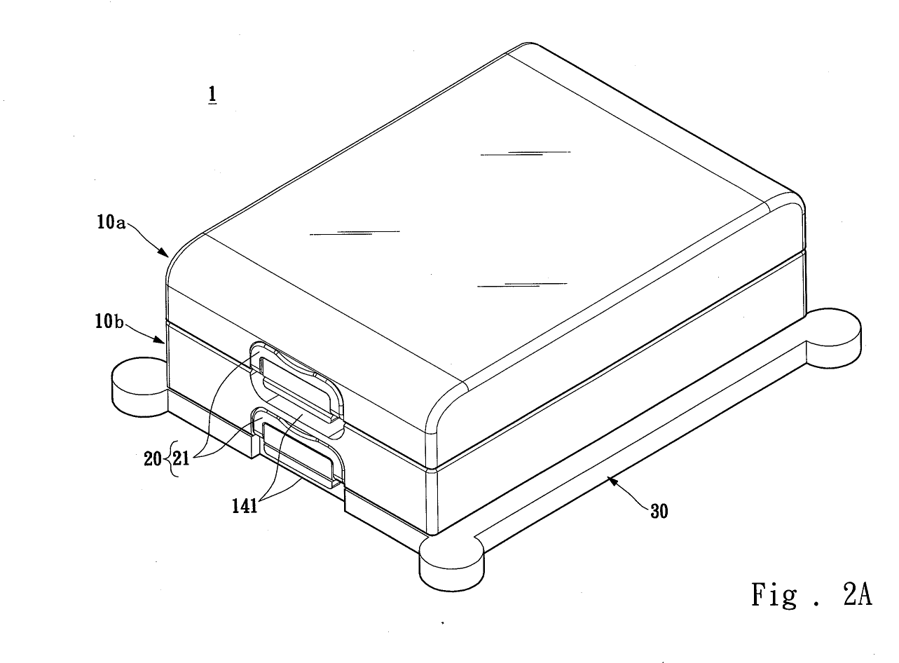

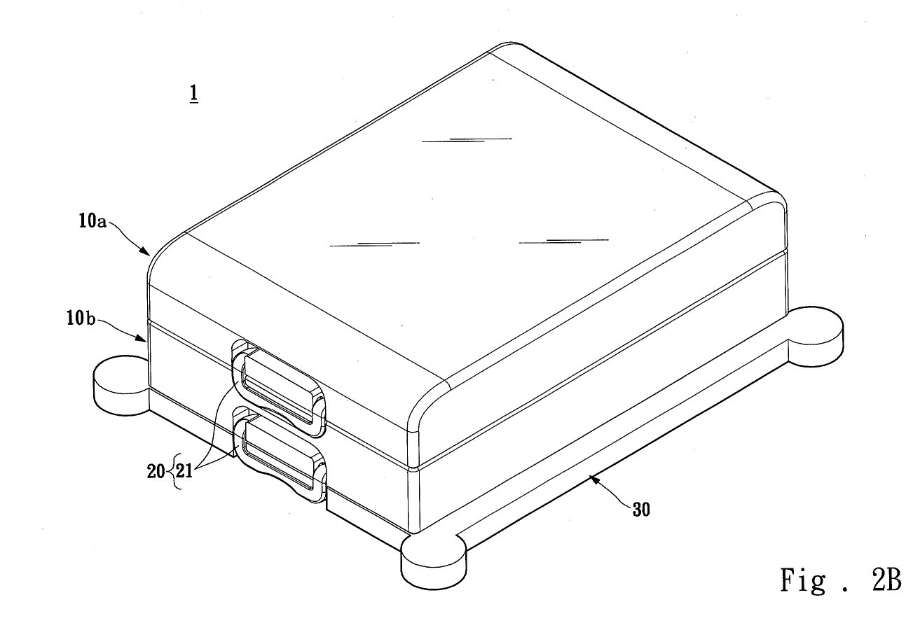

Please referring to FIGS. 1A, 2A and 2B, the fastening unit 20 is located on the body 11 of the electronic devices 10a and 10b. More specifically, the fastening unit 20 includes a plurality of latch arms 21 and a plurality of positioning struts 22. Each latch arm 21 has hinge struts 23 extended from inner walls of distal ends thereof opposing each other. Hence the latch arms 21 can be rotatably positioned on the front wall 111 and rear wall 112 of the body 11. The positioning struts 22 are located relatively to the positioning holes 142.

Please refer to FIG. 3, in this embodiment the electric connection module 12 includes a circuit mother board 121, at least one electric connection element 122, at least one circuit daughter board 123 and at least one connector 124 located on the circuit daughter board 123. The electric connection element 122 includes a first electric contact portion 1221 located on the circuit mother board 121, a second electric contact portion 1222 located on the circuit daughter board 123, and a conductive wire 1223 bridging the first and second electric contact portions 1221 and 1222. The connector 124 is adjacent to the second electric contact portion 1222 and exposed to the opening 13.

It is to be noted that the number of the electric connection element 122, circuit daughter board 123 and connector 124 of the electric connection module 12 is adjustable according to different expansion requirements of the electronic device 10b. For instance, the electric connection module 12 can comprise one circuit mother board 121, two circuit daughter boards 123 located at the upper end and lower end of the circuit mother board 121, one conductive wire 1223 bridging the circuit mother board 121 and circuit daughter boards 123 and two connectors 124 located on the circuit daughter boards 123. More specifically, the connector 124 can be a male connector (including multiple undulate conductive sheets spaced from each other and directed towards the opening), while another connector 124 on the another circuit daughter board 123 is a female connector (including multiple flat conductive sheets spaced from each other and directed towards the opening), thereby the another electronic device 10b can be expanded by stacking other electronic devices with different functions on its upper end and lower end.

Alternatively, the electric connection module 12 of the electronic device 10a can comprise one circuit mother board 121, one circuit daughter board 123 located at one end of the circuit mother board 121, one conductive wire 1223 bridging the circuit mother board 121 and circuit daughter board 123 and one connector 124 located on the circuit daughter board 123. The connector 124 is a male connector. Such type of electronic device 10a usually can be stacked over the top end of the electronic device assembly structure 1 for expansion.

It also should to be noted that the tolerances of the circuit mother board 121 and circuit daughter board 123 of the electric connection module 12 can be adjusted so that the electric connection module 12 can be used in different types of electronic devices 10a and 10b without remaking molds and designing circuits, and therefore can greatly reduce production costs. The connector 124 can be various types of custom made connectors, such as a mini USB, USB 2.0, USB 3.0, DC plug, audio terminal, video terminal, IEEE 1394, HDMI (High-Definition Multimedia Interface), or handheld electronic product connection interface (such as handset or PDA) or the like. In short, when the electronic device assembly structure 1 is assembled, the positioning strut 22 of the electronic device 10a is inserted into the positioning hole 142 of the another electronic device 10b, and the latch arm 21 of the electronic device 10a is rotated from a first position (as shown in FIG. 2A) to a second position (as shown in FIG. 2B) to wedge in the positioning slot 141 of the another electronic device 10b, thereby the two electronic devices 10a and 10b can be coupled together in an integrated manner. The latch arm 21 can be rotated between the first and second positions without extra accessories to fasten the two electronic devices 10a and 10b, hence usability improves.

In addition, in this embodiment the electronic devices 10a and 10b provide different functions. The more electronic devices 10a and 10b included in the electronic device assembly structure 1, the more functions the electronic device assembly structure 1 provides.

### Second Embodiment

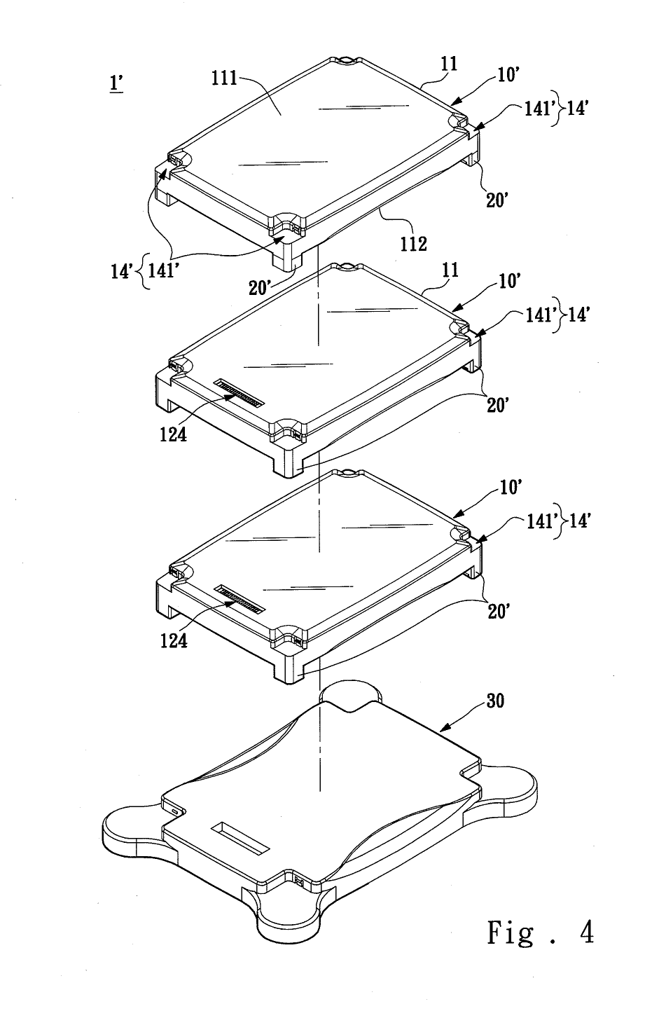

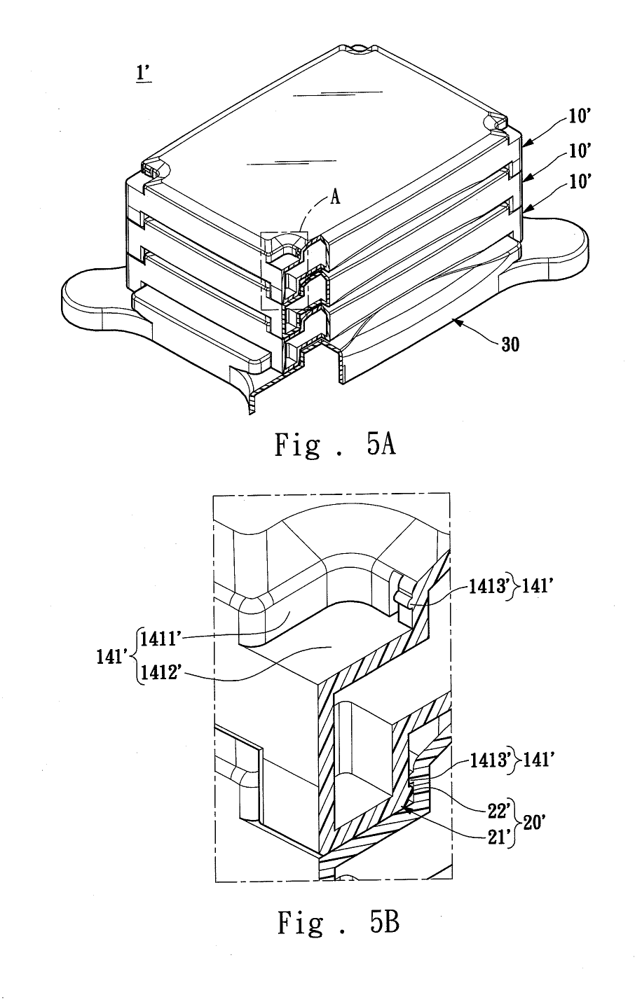

Please refer to FIGS. 4, 5A and 5B for another embodiment of the electronic device assembly structure 1′ of the invention. It differs from the previous embodiment by providing a plurality of coupling slots 141′ on the coupling portion 14′ of one electronic device 10′ and a plurality of coupling arms 21′ on the fastening unit 20′.

More specifically, the coupling slots 141′ are formed on the circumference of the upper wall 111 of the body 11 in an indented manner, and the coupling arms 21′ are formed and extended from the circumference of the lower wall 112 of the body 11 corresponding to the coupling slots 141′. Each coupling slot 141′ includes a slot side wall 1411′ and a slot bottom wall 1412′. The slot side wall 1411′ has an elastic first latch structure 1413′ located thereon, and the coupling arm 21′ has an inelastic second latch structure 22′ on an outer side wall thereof. The first and second latch structures 1413′ and 22′ can be semicircular strut, but this is not the limitation of the shape and structure of the first and second latch structures 1413′ and 22′.

During assembly of the electronic device assembly structure 1′, the coupling arm 21′ of one electronic device 10′ is inserted into the coupling slot 141′ of another electronic device 10′, meanwhile the connector 124 of one electronic device 10′ is also inserted into another connector 124 of another electronic device 10′ to establish power and signal connection. It is to be noted that a stronger force is needed to press the coupling arm 21′ into the coupling slot 141′ or remove therefrom to allow the elastic first latch structure 1413′ to insert into the slot side wall 1411′ of the coupling slot 141′ and latch on the second latch structure 22′, thereby the coupling arm 21′ can be wedged in or removed from the coupling slot 141′.

Efficacy of the embodiments:

According to the embodiments of the invention previously discussed, when the electronic device assembly structure is assembled, multiple electronic devices can be fastened without extra accessories, hence usability improves. Time and manpower needed for assembly can be saved. Moreover, during assembly, all the elements are visible clearly, hence assembly error and damage of the elements also can be reduced.

In addition, with the electronic devices and connection module adopted the modular design fabrication difficulty can be reduced and product consistency is enhanced, and no remaking of molds and circuit design are needed, therefore production cost is lower.

Moreover, in the electronic device assembly structure previous discussed, a heat dissipation channel is formed between any two neighboring electronic devices, hence heat can be quickly dispersed to the atmosphere. Besides, the number of electronic devices also can be increased or decreased (to add or reduce functions of the electronic device assembly structure) according to user's requirements, thus the electronic device assembly structure of the invention can be widely utilized.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. An electronic device assembly structure, comprising:
two electronic devices each including a body with at least one opening formed thereon and an electric connection module located in the body; and
a fastening unit for fastening the two electronic devices together in an integrated manner;
wherein the electric connection modules of the two electronic devices form electric connection through the at least one opening.

2. The electronic device assembly structure of claim 1, wherein the electric connection module includes a circuit mother board, at least one circuit daughter board, at least one electric connection element electrically connected to the circuit mother board and the at least one circuit daughter board, and at least one connector located on the at least one circuit daughter board.

3. The electronic device assembly structure of claim 2, wherein the at least one electric connection element includes a first electric contact portion located on the circuit mother board, a second electric contact portion located on the at least one circuit daughter board and a conductive wire bridging the first electric contact portion and the second electric contact portion.

4. The electronic device assembly structure of claim 3, wherein the at least one connector is adjacent to the second electric contact portion and exposed to the at least one opening.

5. The electronic device assembly structure of claim 1, wherein the body includes a front wall, a rear wall corresponding to the front wall, an upper wall, a lower wall corresponding to the upper wall, and a coupling portion which includes a plurality of positioning slots located on the front wall and the rear wall and a plurality of positioning holes located on the upper wall proximate a circumference of the body and formed on a plane where the at least one opening is located.

6. The electronic device assembly structure of claim 1, wherein the body includes a front wall, a rear wall corresponding to the front wall, an upper wall and a lower wall corresponding to the upper wall, the fastening unit including a plurality of latch arms rotatably located on the front wall and the rear wall and a plurality of positioning struts located on the lower wall proximate a circumference of the body.

7. The electronic device assembly structure of claim 1, wherein the body includes an upper wall and a lower wall corresponding to each other and a coupling portion which includes a plurality of coupling slots indented on a circumference of the upper wall, the fastening unit including a plurality of coupling arms extended from a circumference of the lower wall connectable to the plurality of coupling slots of a neighboring body.

8. The electronic device assembly structure of claim 7, wherein each of the plurality of coupling slots includes a slot side wall and a slot bottom wall.

9. The electronic device assembly structure of claim 8, wherein the slot side wall includes an elastic first latch structure, each of the plurality of coupling arms including an inelastic second latch structure on an outer surface thereof latchable with the first latch structure of a neighboring body.

10. The electronic device assembly structure of claim 1, wherein each of the two electronic devices includes at least one lid rotatably located on the body corresponding to the at least one opening.

11. The electronic device assembly structure of claim 1, wherein each of the two electronic devices includes at least one protective cap corresponding to the at least one opening for latching securely thereon.

12. The electronic device assembly structure of claim 1 further including a base for holding the two electronic devices.
